(19) United States
(12) Patent Application Publication
(10) Pub. No.: US 2022/0145475 A1
(43) Pub. Date: May 12, 2022

(54) Corrosion Prevention Device

(71) Applicant: Nippon Telegraph and Telephone Corporation, Tokyo (JP)

(72) Inventors: Yosuke Takeuchi, Musashino-shi, Tokyo (JP); Takuya Kamisho, Musashino-shi, Tokyo (JP); Shingo Mineta, Musashino-shi, Tokyo (JP); Masayuki Tsuda, Musashino-shi, Tokyo (JP)

(21) Appl. No.: 17/431,332

(22) PCT Filed: Feb. 6, 2020
(86) PCT No.: PCT/JP2020/004450

§ 371 Date: Jan. 19, 2022

(30) Foreign Application Priority Data
Feb. 20, 2019 (JP) 2019-028361

(51) Int. Cl. C23F 13/22; C23F 13/12

(52) U.S. Cl. CPC C23F 13/22; C23F 13/12

(57) ABSTRACT

Provided is an anticorrosion device that does not require the installation of electrical equipment and has no concern about loss of anticorrosion effect due to deterioration of the anode. An anticorrosion device that prevents corrosion of a metal material in a structure, including a thermoelectric power generation unit 10 configured to generate an electromotive force due to a temperature gradient, an anode unit 20 that is responsible for an anode reaction corresponding to the electromotive force, and a cathode unit 30 that is responsible for a cathode reaction corresponding to the electromotive force, in which the cathode unit 30 is a metal material (target metal) in the structure.

### TECHNICAL FIELD

The present invention relates to a metal anticorrosion device, and more particularly to a metal anticorrosion technique inside a reinforced concrete structure (for example, a reinforced concrete utility pole).

### BACKGROUND ART

The most common method of metal anticorrosion is environmental isolation.

As an example, there is an environmental isolation by painting, but in painting, deterioration of the coat due to physical scratching, ultraviolet rays, and rainfall is unavoidable, and even if the coat looks to be in good condition at first glance, there is a risk of undercoat corrosion occurring through defective portions such as pinholes. Other types of environmental isolation include burying in concrete but there is a risk of corrosion of the reinforcing bars through defective portions due to cracks and the like.

Other anticorrosion methods include an electric anticorrosion method. There are two types of electric anticorrosion: a method using an external power source and a sacrificial anode method in which a metal less nobler than the target metal is connected. Electric anticorrosion is often used in combination with painting (Non Patent Literature 1).

### CITATION LIST

### Non Patent Literature

[Non Patent Literature 1] Shinoda et al., Current Status and Future of Electric Anticorrosion and Coating Anticorrosion, Materials and Environment, vol. 63, pp. 180-186 (2014)
[Non Patent Literature 2] Nishikata, Application to Electrochemical Measurement under Thin Film Water and Atmospheric Corrosion Research, Materials and Environment, vol. 65, pp. 120-126 (2016)
[Non Patent Literature 3] Otani et al., Examination of Anticorrosion Effect of Reinforcing Bars in Concrete by Galvanic Anode Type Electric Anticorrosion, Materials and Environment, vol. 64, pp. 462-465 (2015)

### SUMMARY OF THE INVENTION

### Technical Problem

Electric anticorrosion is used when anticorrosion by painting is insufficient or difficult to apply, or when a strong corrosive environment is assumed. When an external power source is used for electric anticorrosion, a dedicated facility is required, and constant energization is required, which increases the cost. When a sacrificial anode is used, special equipment is not required, but if the anode deteriorates, the anticorrosion effect will be lost.

In view of the above-mentioned related-art technique, it is an object of the present invention to provide an anticorrosion device which does not require the installation of electrical equipment and does not have a concern of loss of anticorrosion effect due to deterioration of the anode.

### Means for Solving the Problem

In order to achieve the object described above, the invention according to a first aspect is an anticorrosion device configured to be used for preventing corrosion of a metal material in a structure, including a thermoelectric power generation unit configured to generate electromotive force by a temperature gradient, an anode unit responsible for an anode reaction corresponding to the electromotive force, and a cathode unit responsible for a cathode reaction corresponding to the electromotive force, in which the cathode unit is a metal material in the structure.

The invention according to a second aspect is the invention according to the first aspect, in which the anode unit includes an insoluble material, carbon, or a noble metal.

The invention according to a third aspect is the invention according to the first or second aspect, in which a constant temperature gradient due to heat diffusion from an object and heat dissipation from the thermoelectric power generation unit is utilized by directly installing the thermoelectric power generation unit in the structure.

The invention according to a fourth aspect is the invention according to any one of the first to third aspects, in which corrosion resistance is imparted to the structure by incorporating the thermoelectric power generation unit, the anode unit, and the cathode unit inside the structure in which the metal material is embedded in non-metal.

The invention according to a fifth aspect is the invention according to any one of the first to fourth aspects, in which in the structure, a specific temperature rise of a sunlight-exposed surface of an object in an outdoor environment is used for a high temperature portion in the temperature gradient, and a constant low temperature portion of a sunlight-unexposed surface of an object in an outdoor environment is used for a low temperature portion in the temperature gradient.

The invention according to a sixth aspect is the invention according to the fifth aspect, in which the thermoelectric power generation unit is attached to an inner wall of a hollow portion of a reinforced concrete structure, and the thermoelectric power generation unit is electrically connected to a reinforcing bar and an insoluble material.

The invention according to a seventh aspect is the invention according to the sixth aspect, in which the thermoelectric power generation unit is attached to an inner wall of a hollow portion of a cracked reinforced concrete structure at a cracked position of the cracked reinforced concrete structure, and the thermoelectric power generation unit is electrically connected to a reinforcing bar and an insoluble material to prevent corrosion of a reinforcing bar.

The invention according to an eighth aspect is the invention according to any one of the first to seventh aspects, in which the anode unit is buried in the ground and grounded.

### Effects of the Invention

According to the present invention, it is possible to provide an anticorrosion device that does not require the installation of electrical equipment and resolves concern about loss of anticorrosion effect due to deterioration of the anode.

### BRIEF DESCRIPTION OF DRAWINGS

FIG. 1 is a configuration diagram illustrating an example of an anticorrosion device according to an embodiment of the present invention.

FIG. 2 is a configuration diagram illustrating an example of an anticorrosion device according to an embodiment of the present invention.

FIG. 3 is a diagram illustrating an anticorrosion flow at a cracked position according to an embodiment of the present invention.

FIG. 4 is a configuration diagram illustrating an example of an anticorrosion device according to an embodiment of the present invention.

FIG. 5 is a schematic view of a thermoelectric power generation unit of an anticorrosion device according to an embodiment of the present invention.

FIG. 6 is a configuration diagram illustrating an example of an anticorrosion device according to an embodiment of the present invention.

FIG. 7 is a configuration diagram illustrating an example of an anticorrosion device according to an embodiment of the present invention.

FIG. 8 is a configuration diagram illustrating an example of an anticorrosion device according to an embodiment of the present invention.

### DESCRIPTION OF EMBODIMENTS

Next, an embodiment will be described with reference to the drawings. Meanwhile, in the drawings, same or similar portions are denoted by same or similar reference signs. However, it should be noted that the drawings are schematic, and a relationship between a thickness and planar dimensions, the ratio of thicknesses of layers, and the like are different from those in reality. Thus, specific thicknesses or dimensions should be determined with reference to the following description. In addition, as a matter of course, portions having different mutual dimensional relationships or ratios from those in the drawings are also included.

Further, the embodiments shown below exemplify devices and methods for embodying the technical idea, and do not specify the material, shape, structure, arrangement, and the like of the components to the following. Various modifications may be made to the embodiments within the scope of the aspects.

Overview

The present invention relates to a technique for preventing corrosion of reinforcing bars by generating thermoelectric power using a naturally occurring temperature gradient and using this as a power source for electric anticorrosion. Thermoelectric power generation is a maintenance-free power generation method with no moving parts or consumable parts. According to the present invention, electric anticorrosion of reinforcing bars in a reinforced concrete structure can be implemented at low cost without external energy supply and maintenance.

### Embodiment

In the present embodiment, when an object has a temperature gradient, electric anticorrosion is implemented by generating thermoelectric power using the temperature gradient. When a reinforcing bar in a reinforced concrete structure is subjected to anticorrosion, for example, the concrete column has a hollow structure, so the temperature of the outer wall surface of the concrete column is significantly increased by sunlight, while the temperature within the hollow is not greater than the ambient temperature. As a result of measuring the temperature of the outer wall surface, hollow inner wall surface, and hollow inside of the concrete column when the concrete thickness is 40 mm, during the daytime, the temperature difference from the outer wall surface to the hollow inner wall surface was about 10° C., and the temperature difference from the hollow inner wall surface to the hollow inside was also about 10° C. Therefore, the temperature gradients that can be used are from the temperature gradient of about 10° C. from the concrete outer wall surface to the inner wall surface, the temperature gradient of about 10° C. from the inner wall surface to the hollow inside, and the temperature gradient of about 20° C. from the concrete outer wall surface to the hollow inside, which is the sum of both gradients.

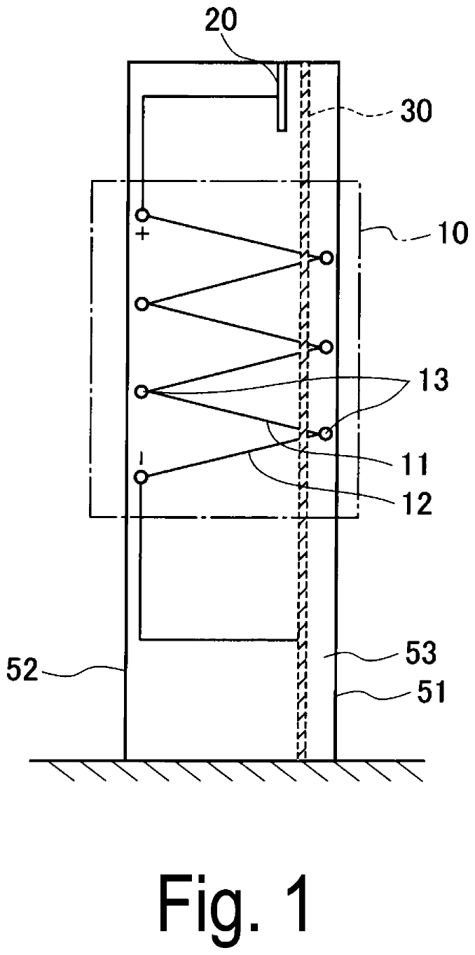

FIG. 1 illustrates an example of an anticorrosion device that utilizes a temperature gradient from the concrete outer wall surface 51 to the inner wall surface. This anticorrosion device is an anticorrosion device that prevents corrosion of a metal material in a structure, and includes, as illustrated in FIG. 1, a thermoelectric power generation unit 10 that generates electromotive force by the temperature gradient, an anode unit 20 responsible for an anode reaction corresponding to the electromotive force, and a cathode unit 30 responsible for a cathode reaction corresponding to the electromotive force, and the cathode unit 30 is a metal material (target metal) in the structure. In FIG. 1, reference numeral 11 is a P material, reference numeral 12 is an N material, reference numeral 13 is a joint, reference numeral 51 is a concrete outer wall surface, reference numeral 52 is a concrete inner wall surface, and reference numeral 53 is a non-metal. The anode unit 20 may include an insoluble material, carbon, or a noble metal.

As described above, in the present embodiment, by directly installing the thermoelectric power generation unit 10 in the structure, the constant temperature gradient due to heat diffusion from the object and heat dissipation from the thermoelectric power generation unit 10 is utilized. That is, by incorporating the thermoelectric power generation unit 10, the anode unit 20, and the cathode unit 30 inside the structure in which the metal material is embedded in non-metal, corrosion resistance can be imparted to the structure.

Here, the thermoelectric power generation unit 10 may be embedded in the concrete or installed along the outer periphery of the concrete structure. When the thermoelectric power generation unit 10 is embedded inside the concrete, the unit is shallowly embedded in the concrete, because the unit is preferably close to the high temperature concrete outer wall surface 51 and the low temperature concrete inner wall surface 52.

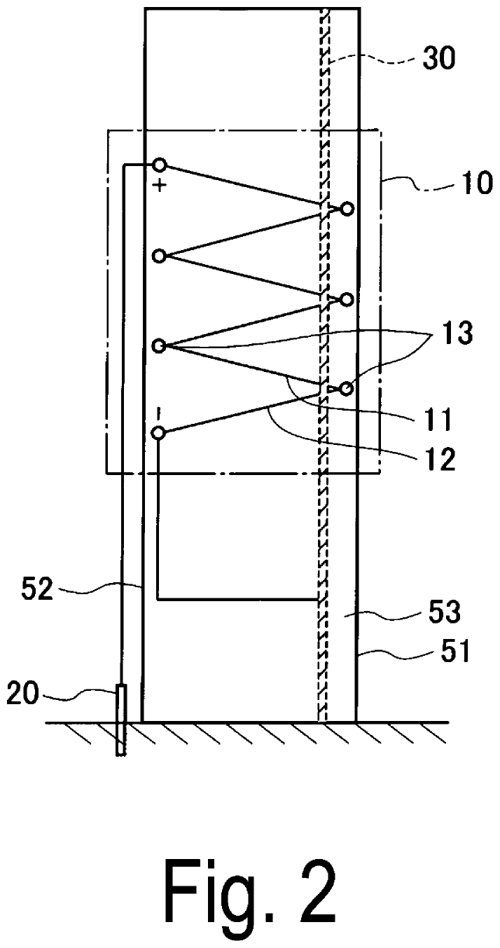

Additionally, while both the cathode unit 30 and the anode unit 20 need to be in a moist environment because they are energized under the condition that an electrochemical reaction occurs, since the environment in which the target metal is corroded is a moist environment, the energization condition is satisfied by placing the cathode unit 30 and the anode unit 20 in the same environment. When it is difficult to arrange the anode unit 20 in the same environment as the cathode unit 30, the insoluble material of the anode unit 20 is immersed in a cell filled with an aqueous solution. As illustrated in FIG. 2, even if the anode unit 20 is buried in the ground and used as a ground, an anticorrosion effect can be obtained by the electromotive force generated by thermoelectric generation.

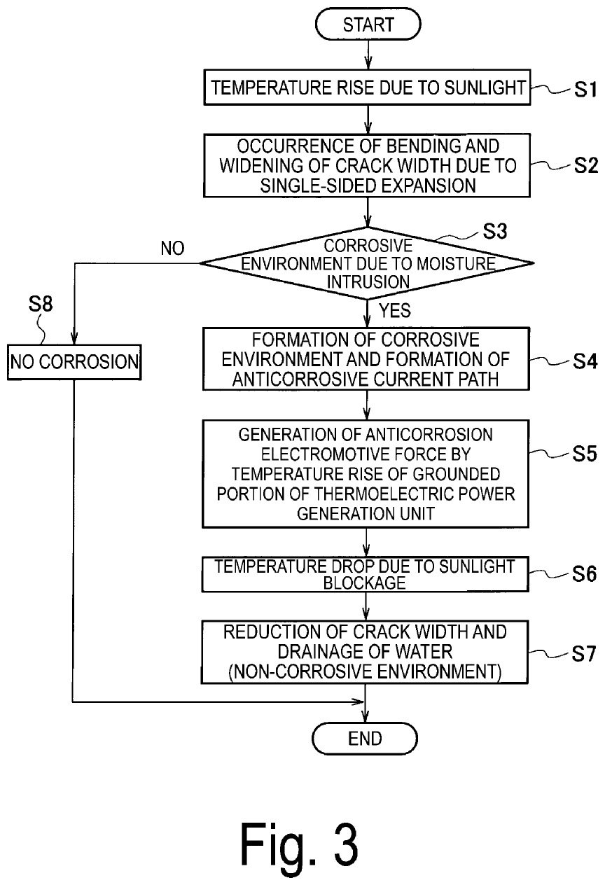

In addition, in facilities such as concrete columns that bend due to expansion due to temperature rise on one side due to sunlight, the crack width increases on the expanded surface. Moisture normally stays inside the crack, but the evaporation of water is promoted by the expansion of the diffusion evaporation path due to the temperature rise and the expansion of the crack width. It is known that corrosion is promoted when the water film thickness on the metal surface fluctuates due to evaporation of water (Non Patent Literature 2), corrosion is thought to be promoted in structures that bend due to sunlight. Therefore, it is useful for reinforcing bar anticorrosion to install an anticorrosion device on the sunlight-exposed surface having cracks, or to incorporate an anticorrosion mechanism. The flowchart of the development of the anticorrosion function at the cracked position is illustrated in FIG. 3.

That is, as shown in FIG. 3, when there is a temperature rise due to sunlight, bending and expansion of crack width due to one-sided expansion occurs, corrosive environment is formed by moisture intrusion, and an anticorrosion current path is formed (steps S1→S2→S3→S4). When an anticorrosion device is installed on a cracked sunlight-exposed surface or an anticorrosion mechanism is built in, anticorrosion electromotive force is generated due to the temperature rise of the grounded portion of the thermoelectric power generation unit 10, the temperature drops due to sunlight blockage, the crack width is reduced, and water is discharged, whereby a non-corrosive environment can be achieved (steps S5→S6→S7).

Thus, in the present embodiment, in a structure, the specific temperature rise of the sunlight-exposed surface of the object in the outdoor environment is used for the high temperature portion in the temperature gradient, and for the low temperature portion in the temperature gradient, the constant low temperature portion of the sunlight-unexposed surface of the object in the outdoor environment is used. Specifically, the thermoelectric power generation unit 10 is attached to the inner wall of the hollow portion of the cracked reinforced concrete structure at the cracked position of the cracked reinforced concrete structure, and the thermoelectric power generation unit 10 is electrically connected to the reinforcing bar and the insoluble material to prevent corrosion of the reinforcing bar.

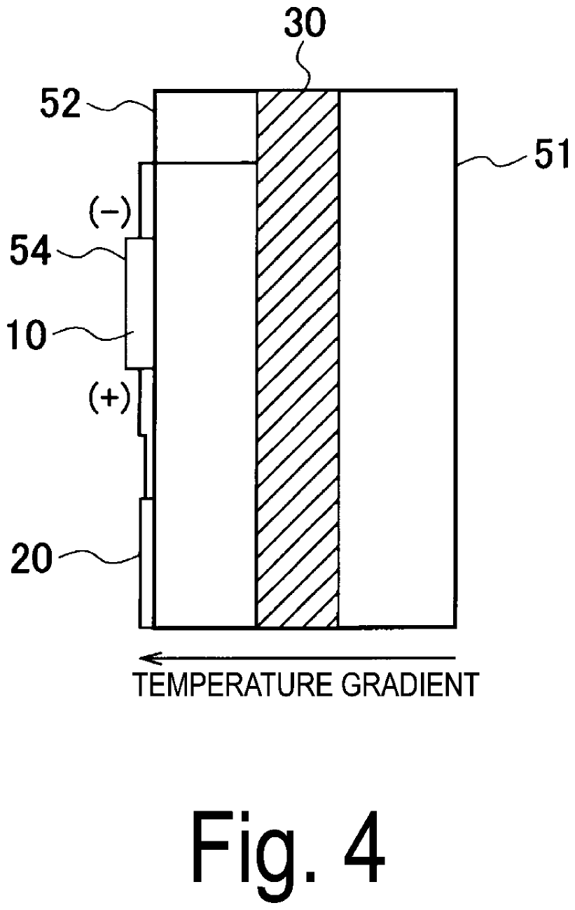

FIG. 4 illustrates an example of an anticorrosion device that utilizes a temperature gradient from the concrete inner wall surface 52 to the hollow inside. In this configuration, the thermoelectric power generation unit 10 is attached and installed on the concrete inner wall surface 52, the installation surface is on the high temperature side (concrete inner wall surface 52 side), the hollow inner side 54 is on the low temperature side, and a temperature gradient is generated inside the thermoelectric power generation unit 10. That is, the thermoelectric power generation unit 10 is attached to the inner wall of the hollow portion of the reinforced concrete structure, and the thermoelectric power generation unit 10 is electrically connected to the reinforcing bar and the insoluble material to prevent corrosion of the reinforcing bar.

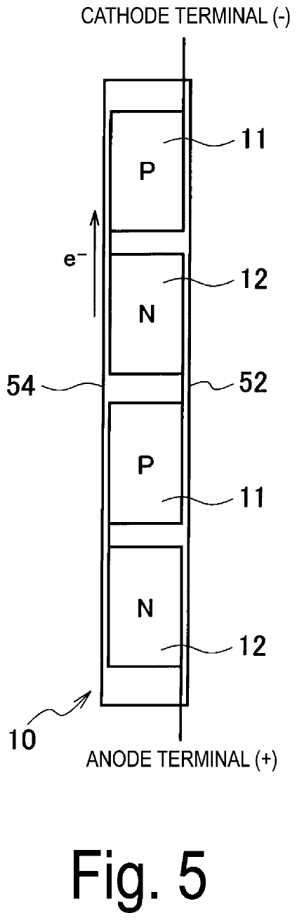

FIG. 5 illustrates a schematic diagram of the thermoelectric power generation unit 10. As illustrated in FIG. 5, the thermoelectric power generation unit 10 includes a P material 11 and an N material 12, and the P material 11 and the N material 12 are alternately arranged in series.

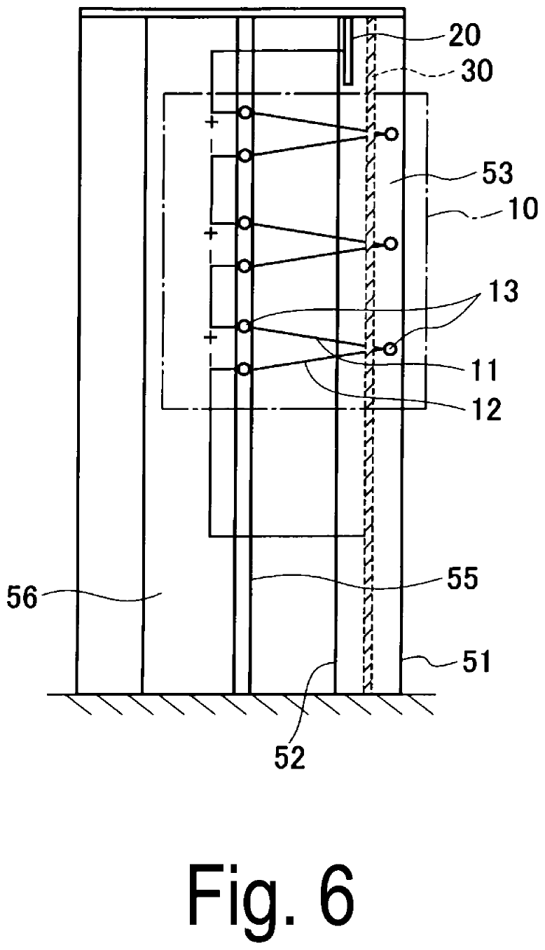

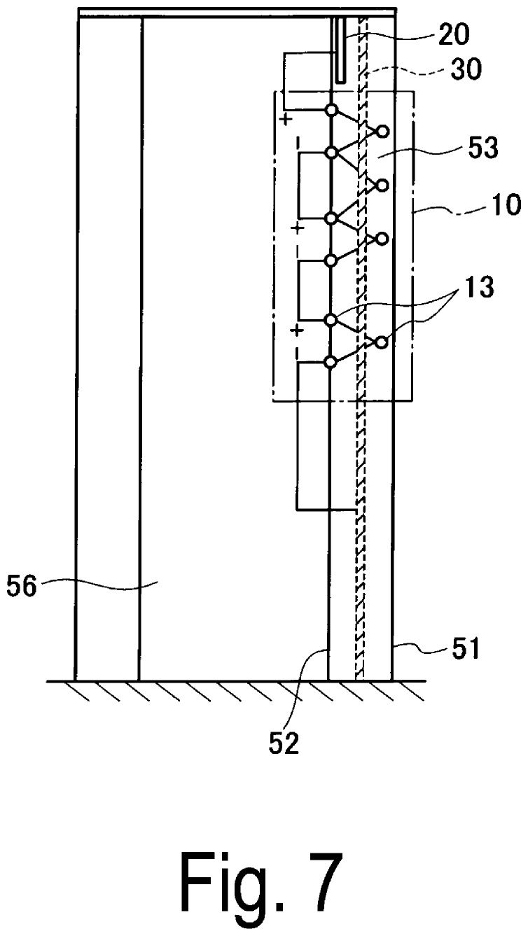

FIGS. 6 and 7 illustrate an example of an anticorrosion device that utilizes a temperature gradient from the concrete outer wall surface 51 to the hollow inside 56. Reference numeral 55 in FIG. 6 indicates a support column (reference point). These configurations are the same as those in FIG. 1, except that the low temperature portion is exposed inside the hollow inside 56.

In any of the above configuration examples, the number of connected elements in the thermoelectric power generation unit 10 may be freely designed according to a desired electromotive force. As the electromotive force of the thermoelectric power generation unit 10, for example, it is sufficient to design the thermoelectric power generation unit 10 sufficient to realize a depolarization amount of 100 mV or more (Non Patent Literature 3) with a temperature gradient of 20° C. The electromotive force for a temperature gradient in the thermoelectric power generation unit 10 can be designed by a method of connecting a plurality of dissimilar metal joints or a plurality of semiconductor connections in series (Non Patent Literature 3).

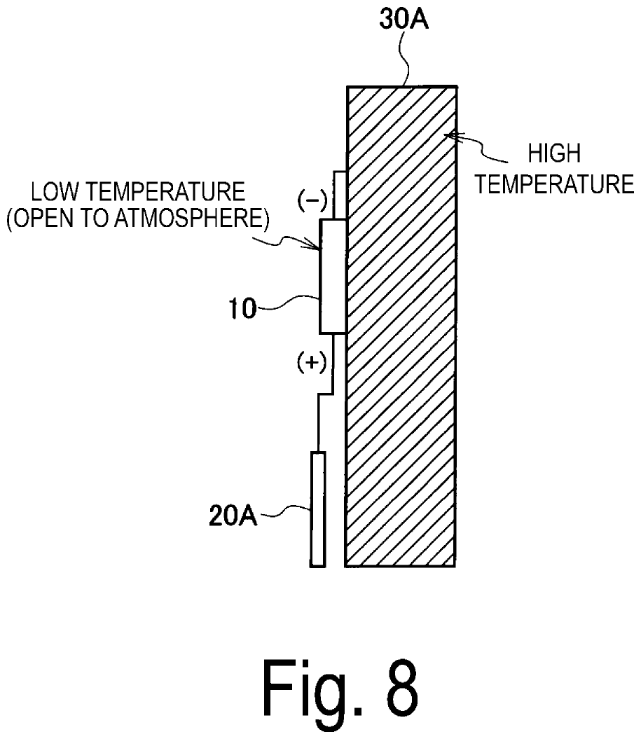

In the case of metal tanks and pipes for storing hot liquids or gases inside, the inside is always hot and the outside is ambient temperature. Therefore, a temperature gradient from the temperature of the contents to the atmospheric temperature is constantly generated in the target metal. Therefore, as illustrated in FIG. 8, by installing the thermoelectric power generation unit 10 of FIG. 5 on the target metal 30A, connecting the target metal 30A to the cathode unit 30, and connecting the insoluble material 20A to the anode unit 20, maintenance-free anticorrosion can be achieved.

As described above, according to the present embodiment, thermoelectric power generation using the temperature gradient generated in the object eliminates the need for electrical energy supply from dedicated equipment, and the use of an insoluble material for the anode can prevent deterioration or loss of anticorrosion performance due to anode deterioration. That is, there is no need to install electrical equipment, and there is no concern about loss of anticorrosion effect due to deterioration of the anode. Therefore, maintenance-free anticorrosion utilizing renewable energy can be achieved with a simple configuration.

As described above, the present embodiment is an anticorrosion device that prevents corrosion of a metal material in a structure, including the thermoelectric power generation unit 10 that generates an electromotive force due to the temperature gradient, the anode unit 20 that is responsible for the anode reaction corresponding to the electromotive force, and the cathode unit 30 that is responsible for the cathode reaction corresponding to the electromotive force, in which the cathode unit 30 is a metal material (target metal) in the structure.

Specifically, an insoluble material, carbon or a noble metal is used for the anode unit 20.

Further, by directly installing the thermoelectric power generation unit 10 in the structure, a constant temperature gradient due to heat diffusion from the object and heat dissipation from the thermoelectric power generation unit 10 is utilized.

Further, by incorporating the thermoelectric power generation unit 10, the anode unit 20, and the cathode unit 30 inside the structure in which the metal material is embedded in non-metal, the structure is imparted with corrosion resistance.

Further, in the structure, the specific temperature rise of the sunlight-exposed surface of the object in the outdoor environment is used for the high temperature portion in the temperature gradient, and the constant low temperature portion of the sunlight-unexposed surface of the object in the outdoor environment is used for the low temperature portion in the temperature gradient.

Further, the thermoelectric power generation unit 10 is attached to the inner wall of the hollow portion of the reinforced concrete structure, and the thermoelectric power generation unit 10 is electrically connected to the reinforcing bar and the insoluble material to prevent corrosion of the reinforcing bar.

Further, the thermoelectric power generation unit 10 is attached to the inner wall of the hollow portion of the cracked reinforced concrete structure at the cracked position of the cracked reinforced concrete structure, and the thermoelectric power generation unit 10 is electrically connected to the reinforcing bar and the insoluble material to prevent corrosion of the reinforcing bar.

The anode unit 20 is buried in the ground and grounded.

### Other Embodiments

As described above, although several embodiments have been described, it should be understood that the description and drawings which are parts of the disclosure are merely illustrative, and are not intended to limit the embodiments. From the disclosure, various alternative embodiments, examples, and operational techniques will be apparent to those skilled in the art.

As such, the embodiments include various aspects not described herein.

### REFERENCE SIGNS LIST

10 Thermoelectric power generation unit
11 P material
12 N material
13 Joint
20 Anode unit
30 Cathode unit
51 Concrete outer wall surface
52 Concrete inner wall surface
53 Non-metal
54 Hollow inner side
55 Support column (reference point)
56 Hollow inside

1. An anticorrosion device configured to be used for preventing corrosion of a metal material in a structure, comprising:
a thermoelectric power generation unit configured to generate electromotive force by a temperature gradient;
an anode unit responsible for an anode reaction corresponding to the electromotive force; and
a cathode unit responsible for a cathode reaction corresponding to the electromotive force, wherein
the cathode unit is a metal material in the structure.

2. The anticorrosion device according to claim 1, wherein the anode unit comprises an insoluble material, carbon, or a noble metal.

3. The anticorrosion device according to claim 1 or 2, wherein a constant temperature gradient due to heat diffusion from an object and heat dissipation from the thermoelectric power generation unit is utilized by directly installing the thermoelectric power generation unit in the structure.

4. The anticorrosion device according to any one of claims 1 to 3, wherein corrosion resistance is imparted to the structure by incorporating the thermoelectric power generation unit, the anode unit, and the cathode unit inside the structure in which the metal material is embedded in non-metal.

5. The anticorrosion device according to any one of claims 1 to 4, wherein in the structure, a specific temperature rise of a sunlight-exposed surface of an object in an outdoor environment is used for a high temperature portion in the temperature gradient, and a constant low temperature portion of a sunlight-unexposed surface of an object in an outdoor environment is used for a low temperature portion in the temperature gradient.

6. The anticorrosion device according to claim 5, wherein the thermoelectric power generation unit is attached to an inner wall of a hollow portion of a reinforced concrete structure, and the thermoelectric power generation unit is electrically connected to a reinforcing bar and an insoluble material to prevent corrosion of a reinforcing bar.

7. The anticorrosion device according to claim 6, wherein the thermoelectric power generation unit is attached to an inner wall of a hollow portion of a cracked reinforced concrete structure at a cracked position of the cracked reinforced concrete structure, and the thermoelectric power generation unit is electrically connected to a reinforcing bar and an insoluble material to prevent corrosion of a reinforcing bar.

8. The anticorrosion device according to any one of claims 1 to 7, wherein the anode unit is buried in ground and grounded.
